(19) United States
(12) Patent Application Publication
(10) Pub. No.: US 2009/0117705 A1
(43) Pub. Date: May 7, 2009

(54) METHOD OF FORMING ISOLATION LAYER OF SEMICONDUCTOR MEMORY DEVICE

(75) Inventor: Kwang Seok Oh, Yeoju-gun (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,844

(22) Filed: Jun. 27, 2008

(30) Foreign Application Priority Data
Nov. 2, 2007 (KR) 2007-111733

(51) Int. Cl. H01L 21/762

(52) U.S. Cl. 438/424; 257/E21.545

(57) ABSTRACT

The present invention relates to a method of forming isolation layers of a semiconductor device. According to a method of forming isolation layers of a semiconductor device in accordance with an aspect of the present invention, a tunnel insulating layer, a charge trap layer, and a hard mask layer are sequentially formed over a semiconductor substrate. First trenches are formed by etching the hard mask layer, the charge trap layer, the tunnel insulating layer, and the semiconductor substrate. A spacer layer is formed on the entire surface including the first trenches. Second trenches are formed by etching the spacer layer, which is formed at a bottom of the first trenches, and the semiconductor substrate. An insulating layer for isolation is formed on the entire surface including the second trenches.

### CROSS-REFERENCES TO RELATED APPLICATIONS

The present application claims priority to Korean patent application number 10-2007-111733, filed on Nov. 2, 2007, which is incorporated by reference in its entirety.

### BACKGROUND OF THE INVENTION

The present invention relates to a method of forming an isolation layer of a semiconductor device and, more particularly, to a method of forming isolation layers which can prohibit voids from occurring due to a bowing effect on the sidewalls of the trenches.

In general, in semiconductor devices requiring a design rule of 70 nm or less, a shallow trench isolation (STI) process that is able to significantly reduce stress applied to a wafer substrate is generally used. The STI process is a technology for forming a trench having a specific depth in a semiconductor substrate, depositing an oxide layer in the trench using a chemical vapor deposition (CVD) method, and etching the oxide layer using a chemical mechanical polishing (CMP), thus forming an isolation layer.

FIG. 1 is a photograph showing isolation layers of a conventional semiconductor device.

Referring to FIG. 1, according to a conventional method of forming isolation layers of a semiconductor device, a tunnel insulating layer, a polysilicon layer, and hard mask patterns are sequentially formed over a semiconductor substrate. The hard mask patterns, the polysilicon layer and the tunnel insulating layer are sequentially etched to thereby form isolation trenches. At the time of the trench etch process, a boundary portion inside the trench between the tunnel insulating layer and the semiconductor substrate is etched at a greater rate than other portions thereof, so a bowing effect is generated (i.e., the trench opening is more narrow towards the top and bottom of the trench and wider towards the middle of the trench). Here, the bowing effect causes voids in a subsequent gap-fill process of the insulating layer. Accordingly, the electrical properties of the semiconductor device are degraded.

### BRIEF SUMMARY OF THE INVENTION

The present invention relates to a method of forming isolation layers of a semiconductor device, in which first trenches of semiconductor elements are formed, a spacer is formed on sidewalls of the first trenches, and second trenches are formed by an etch process using the spacer as a mask, so that a bowing effect can be prohibited from occurring on the sidewalls of the trenches, voids can be prevented from occurring in a subsequent gap-fill process of an insulating layer, and the electrical properties of the device can be improved.

According to a method of forming isolation layers of a semiconductor device in accordance with an aspect of the present invention, a tunnel insulating layer, a charge trap layer, and a hard mask layer are sequentially formed over a semiconductor substrate. First trenches are formed by etching the hard mask layer, the charge trap layer, the tunnel insulating layer, and the semiconductor substrate. A spacer layer is formed on the entire surface including the first trenches. Second trenches are formed by etching the spacer layer, which is formed at a bottom of the first trenches, and the semiconductor substrate. An insulating layer for isolation is formed on the entire surface including the second trenches.

The hard mask layer can be formed by sequentially stacking a nitride layer for a hard mask and an oxide layer for a hard mask. The nitride layer for the hard mask can be formed to a thickness of 50 to 1000 angstroms. The oxide layer for the hard mask can be formed to a thickness of 100 to 3000 angstroms.

In the formation of the first trenches and the second trenches, HBr, O₂, Cl₂, CHF₃, CF₄, He, and Ar gases can be used as etch gases. Each of the first trenches can have a depth of 50 to 1000 angstroms. Each of the second trenches can have a depth of 1500 to 4000 angstroms.

The spacer layer can be formed of an oxide layer. The spacer layer can be formed to a thickness of 0.5 to 10 angstroms.

### BRIEF DESCRIPTION OF THE DRAWINGS

FIG. 1 is a photograph showing isolation layers of a conventional semiconductor device; and

FIGS. 2 to 7 are sectional views illustrating a method of forming isolation layers of a semiconductor device in accordance with an embodiment of the present invention.

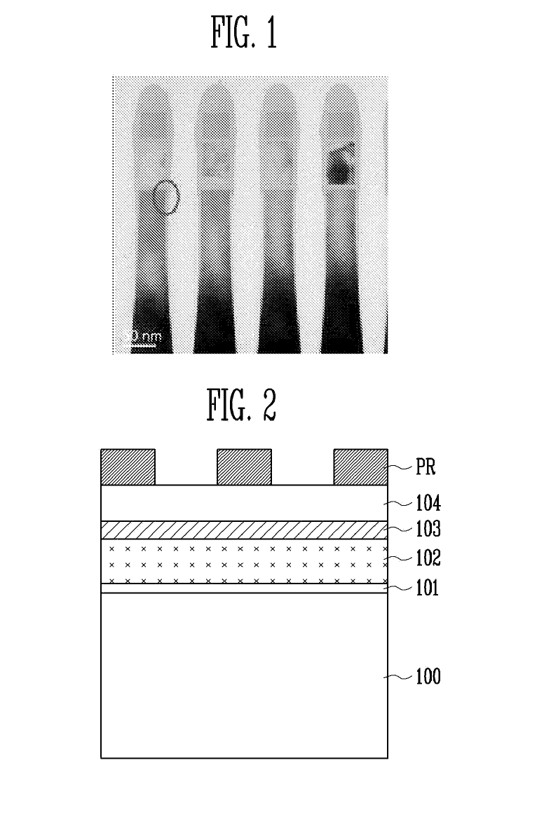

### DESCRIPTION OF SPECIFIC EMBODIMENTS

A specific embodiment according to the present invention will be described with reference to the accompanying drawings. However, the present invention is not limited to the disclosed embodiment, but may be implemented in various manners. The embodiment is provided to complete the disclosure of the present invention and to allow those having ordinary skill in the art to understand the scope of the present invention. The present invention is defined by the category of the claims.

FIGS. 2 to 6 are sectional views illustrating a method of forming isolation layers of a semiconductor device in accordance with an embodiment of the present invention.

Referring to FIG. 2, a tunnel insulating layer 101, a conductive layer 102 for a floating gate, a nitride layer 103 for a hard mask, and an oxide layer 104 for a hard mask are sequentially formed over a semiconductor substrate 100.

The tunnel insulating layer 101 can be formed of an oxide layer. The tunnel insulating layer 101 can be deposited to a thickness of 50 to 100 angstroms using a wet oxidization process and then subjected to an N₂O annealing process in order to incorporate nitrogen within the tunnel insulating layer 101. Thus, the charge trap density can be reduced and reliability can be improved. The conductive layer 102 can have a dual layer having an amorphous polysilicon layer not containing an impurity (i.e., undoped poly) and a polysilicon layer containing an impurity (i.e., doped poly). The conductive layer 102 can be formed using a SiH₄ gas and a PH₃ gas as source gases in a temperature range of 500 to 550 degrees Celsius. The conductive layer 102 can be deposited to a thickness of 100 to 1000 angstroms. The nitride layer 103 can be deposited to a thickness of 50 to 1000 angstroms. The oxide layer 104 can be deposited to a thickness of 100 to 3000 angstroms.

Photoresist patterns PR are formed on the oxide layer 104.

Referring to FIG. 3, the oxide layer 104 and the insulating layer 103 are etched by an etch process using the photoresist patterns as a mask, thus forming hard mask patterns 103, 104. The photoresist patterns are then removed.

The conductive layer 102 is etched using the hard mask patterns 103, 104 as an etch mask so that the tunnel insulating layer 101 is exposed.

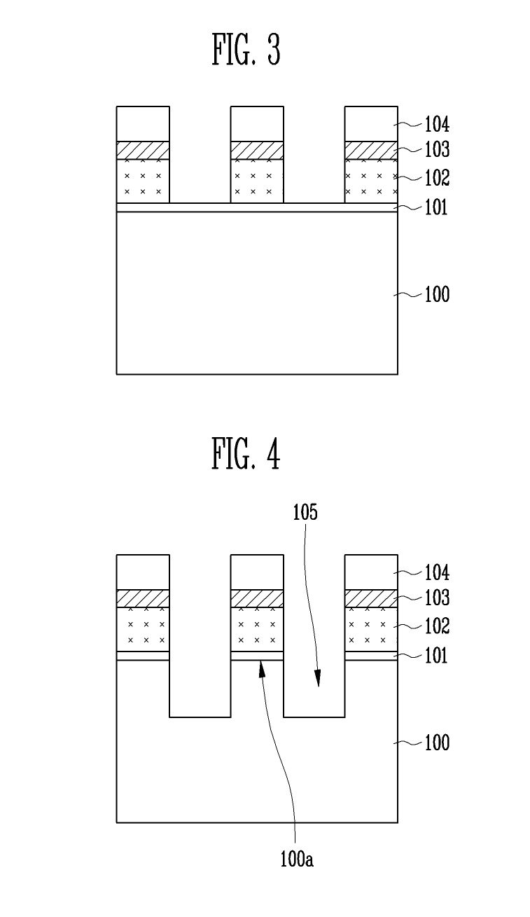

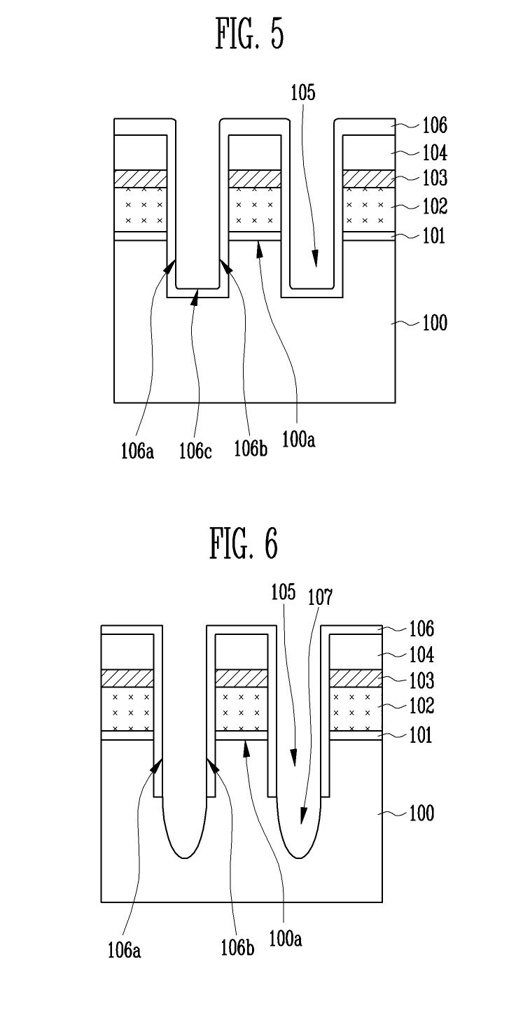

Referring to FIG. 4, the exposed tunnel insulating layer 101 and the semiconductor substrate 100 are etched to thereby form first trenches 105. The first trench 105 can have a depth of 50 to 1000 angstroms when measured from an upper surface 100a of the semiconductor substrate 100. The etch process of the first trenches 105 can be performed using HBr, O₂, Cl₂, CHF₃, CF₄, He, and Ar gases. In one embodiment, the first trench 105 has a depth of at least 100 angstroms. In another embodiment, the first trench 105 has a depth of at least 200 angstroms. In yet another embodiment, the first trench 105 has a depth of at least 300 angstroms, or at least 400 angstroms, or at least 500 angstroms, or at least 600 angstroms.

Referring to FIG. 5, a spacer layer 106 is formed on the entire surface including the first trenches 105. The spacer layer 106 can be formed of an oxide layer. The spacer layer 106 can be formed to a thickness of 0.5 to 10 angstroms. In one implementation, the thickness is 3-4 angstroms. In another implementation, the thickness is 3-6 angstroms.

For each first trench 105, the spacer layer 106 has first and second side portions 106a and 106b and a bottom portion 106c that connects the first and second side portions 106a and 106b. The first and second side portions 106a and 106b are formed on the sidewalls of the first trench 105. The bottom portion 106c is formed on the bottom of the first trench 105.

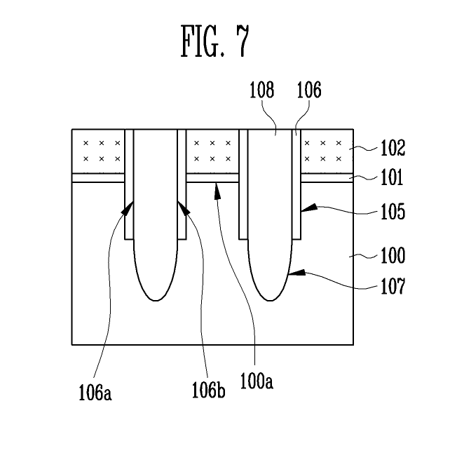

Referring to FIG. 6, The bottom portion 106c of the spacer layer 106 is etched. The semiconductor substrate 100 underlying the bottom portion 106c is etched to increase the depth of the first trench, thereby forming second trenches 107. In the present embodiment, the bottom portions 106c and the substrate 100 are etched using the same etch process. In other embodiments, different etch processes may be used. The second trenches 107 have a depth of 1500 to 4000 angstroms when measure from the upper surface 100a of the semiconductor substrate 100. The etch process of the second trenches 107 can be performed using HBr, O₂, Cl₂, CHF₃, CF₄, He, and Ar gases. The trenches obtained by forming the second trenches may be referred to as the first and second trenches or simply as the second trenches.

Referring to FIG. 7, an insulating layer 108 for isolation is formed on the entire surface including the second trenches 107, thereby gap-filling the second trenches 107. Thereafter, the nitride layer for the hard mask is exposed by performing a polishing process, e.g., a chemical mechanical polishing process. Isolation structures 108 are formed. Each isolation structure 108 includes the first and second side portions 106a and 106b that extends into the semiconductor substrate 100 for a given depth that corresponds to the depth of the first trench 105. For example, if the first trench 105 has a depth of 100 angstroms when measured from the upper surface 100a of the semiconductor substrate 100, then the first and second side portions 106a and 106b extends about 100 angstroms into the substrate 100 when measured from the upper surface 100a.

After the nitride layer for the hard mask is removed, a top surface of the isolation layer 108 is etched such that the effective field oxide height (EFH) of the isolation layer becomes a desired level.

As described above, according to the present invention, first isolation trenches of semiconductor elements are formed, a spacer is formed on sidewalls of the first trenches, and second trenches are formed by an etch process using the spacer as a mask. Thus, a bowing effect can be prohibited from occurring on the sidewalls of the trenches and voids can be prevented from occurring in a subsequent gap-fill process of the insulating layer. Accordingly, the electrical properties of the device can be improved.

The embodiment disclosed herein has been proposed to allow a person skilled in the art to easily implement the present invention, and the person skilled in the part may implement the present invention in various ways. Therefore, the scope of the present invention is not limited by or to the embodiment as described above, and should be construed to be defined only by the appended claims and their equivalents.

What is claimed is:

1. A method for forming a semiconductor device, the method comprising:
forming a tunnel insulating layer over a semiconductor substrate and a charge trap layer over the tunnel insulating layer;
etching the charge trap layer, the tunnel insulating layer, and the semiconductor substrate to form a first trench, the first trench having a first depth when measured from an upper surface of the semiconductor substrate;
forming a spacer layer within the first trench and over the charge trap layer, the spacer layer having first and second side portions and a bottom portion connecting the first and second side portions;
etching the bottom portion of the spacer layer and the semiconductor substrate to form a second trench having a second depth when measured from the upper surface of the semiconductor substrate; and
forming an isolation structure within the first and second trenches.

2. The method of claim 1, wherein HBr, O₂, Cl₂, CHF₃, CF₄, He, and Ar gases are used to etch the first trench and the second trench.

3. The method of claim 1, wherein the first trench has a depth of 50 to 1000 angstroms.

4. The method of claim 1, wherein the second trench has a depth of 1500 to 4000 angstroms.

5. The method of claim 1, wherein the spacer layer includes an oxide layer.

6. The method of claim 1, wherein the spacer layer is formed to a thickness of 0.5 to 10 angstroms.

7. The method of claim 1, wherein the spacer layer has a thickness of no more than 6 angstroms.

8. The method of claim 1, wherein the first depth of the first trench is at least 300 angstroms, wherein the first and second side portions each extends at least 300 angstroms into the semiconductor substrate from the upper surface of the semiconductor substrate.

9. The method of claim 8, wherein the first and second side portions each extend a given distance above the upper surface of the semiconductor substrate and contact sidewalls of the tunnel insulating layer and sidewalls of the charge trap layer.

10. A method of forming isolation layers of a semiconductor device, the method comprising:
sequentially forming a tunnel insulating layer, a charge trap layer, and a hard mask layer over a semiconductor substrate;
forming a first trench by etching the hard mask layer, the charge trap layer, the tunnel insulating layer, and the semiconductor substrate;
forming a spacer layer on the entire surface including the first trench, the spacer layer defining a first side portion against a first sidewall of the first trench, a second side portion against a second sidewall of the first trench, and a bottom portion connecting the first and second side portions;
forming a second trench by etching the bottom portion of the spacer layer and the semiconductor substrate; and
forming an insulating layer on the entire surface, the insulating layer filling the first and second trenches to form an isolation structure.

11. The method of claim 10, wherein the hard mask layer is formed by sequentially stacking a nitride layer for a hard mask and an oxide layer for a hard mask.

12. The method of claim 11, wherein the nitride layer for the hard mask is formed to a thickness of 50 to 1000 angstroms.

13. The method of claim 11, wherein the oxide layer for the hard mask is formed to a thickness of 100 to 3000 angstroms.

14. The method of claim 10, wherein HBr, O₂, Cl₂, CHF₃, CF₄, He, and Ar gases are used as etch gases to form the first and second trenches.

15. The method of claim 10, wherein the first trench has a depth of 50 to 1000 angstroms.

16. The method of claim 10, wherein the second trench has a depth of 1500 to 4000 angstroms.

17. The method of claim 10, wherein the spacer layer is formed of an oxide layer.

18. The method of claim 10, wherein the spacer layer is formed to a thickness of 0.5 to 10 angstroms.

19. A method for forming an isolation structure of a semiconductor device, the method comprising:
forming a first trench by etching an isolation region of a semiconductor substrate;
forming a spacer layer on the entire surface including the first trench;
forming a second trench by etching the spacer layer, which is formed at a bottom of the first trenches and the semiconductor substrate; and
gap-filling at least the second trench with an insulating layer to form the isolation structure.
